(19) United States
(12) Patent Application Publication
(10) Pub. No.: US 2026/0150667 A1
(43) Pub. Date: May 28, 2026

(54) SEMICONDUCTOR PACKAGE

(71) Applicant: Samsung Electronics Co., Ltd., Suwon-si (KR)

(72) Inventors: Kyonghwan Koh, Suwon-si (KR); Gyuhyeong Kim, Suwon-si (KR); Yuhyeok Kim, Suwon-si (KR); Junhyeung Jo, Suwon-si (KR)

(21) Appl. No.: 19/290,541

(22) Filed: Aug. 5, 2025

(30) Foreign Application Priority Data
Nov. 25, 2024 (KR) 10-2024-0169865

(51) Int. Cl. H01L 23/367; H01L 21/48; H01L 21/56; H01L 23/00; H01L 23/31; H01L 23/373; H01L 25/065; H01L 25/18; H10B 80/00; H10D 80/30

(52) U.S. Cl. CPC H10W 40/22; H10W 40/037; H10W 40/258; H10W 74/01; H10W 74/117; H10W 90/00; H10B 80/00; H10D 80/30; H10W 72/5473; H10W 90/24; H10W 90/288; H10W 90/732; H10W 90/734; H10W 90/736; H10W 90/754

(57) ABSTRACT

A semiconductor package includes a package substrate, a semiconductor chip stack including a plurality of semiconductor chips arranged on, and electrically connected to, the package substrate, a plurality of heat dissipation posts spaced apart from the semiconductor chip stack on the package substrate, a heat dissipation plate on upper surfaces of the plurality of heat dissipation posts, and an encapsulant surrounding, with respect to a top-down view of the semiconductor package, each of the semiconductor chip stack, the plurality of heat dissipation posts, and the heat dissipation plate on the package substrate.

### CROSS-REFERENCE TO RELATED APPLICATION(S)

This application claims benefit of priority to Korean Patent Application No. 10-2024-0169865 filed on Nov. 25, 2024 in the Korean Intellectual Property Office, the disclosure of which is incorporated herein by reference in its entirety.

### BACKGROUND

The present inventive concept relates to a semiconductor package.

As electronic devices have become lighter with higher performance, the development of miniaturized and high-performance semiconductor chips has been required. In order to improve the reliability of high-performance semiconductor chips, the importance of heat dissipation characteristics of a semiconductor package has increased.

### SUMMARY

An aspect of the present inventive concept is to provide a semiconductor package with improved heat dissipation characteristics and enhanced reliability.

According to an aspect of the present inventive concept, a semiconductor package includes: a package substrate, a semiconductor chip stack including a plurality of semiconductor chips arranged on, and electrically connected to, the package substrate, a plurality of heat dissipation posts spaced apart from the semiconductor chip stack on the package substrate, a heat dissipation plate on upper surfaces of the plurality of heat dissipation posts, and an encapsulant surrounding, with respect to a top-down view of the semiconductor package, each of the semiconductor chip stack, the plurality of heat dissipation posts, and the heat dissipation plate on the package substrate.

According to an aspect of the present inventive concept, a semiconductor package includes: a package substrate, a heat dissipation structure on the package substrate, wherein the heat dissipation structure includes a heat dissipation plate spaced apart from the package substrate in a vertical direction and a plurality of heat dissipation posts extending in the vertical direction between the heat dissipation plate and the package substrate, a plurality of semiconductor chips below the heat dissipation plate on the package substrate, wherein the plurality of semiconductor chips include an uppermost semiconductor chip disposed on a highest level, and a spacer structure between the heat dissipation plate and the plurality of semiconductor chips, wherein a footprint of the spacer structure, with respect to a top-down view of the semiconductor package, is smaller than a footprint of each of the plurality of semiconductor chips.

According to an aspect of the present inventive concept, a semiconductor package includes: a semiconductor chip stack including a plurality of semiconductor chips stacked in a vertical direction, the plurality of semiconductor chips including chip pads located at upper surfaces thereof, respectively; a package substrate below the semiconductor chip stack and including upper pads located at an upper surface thereof; wire bonds extending from the chip pads of the plurality of respective semiconductor chips to the upper pads of the package substrate; a spacer structure on the plurality of semiconductor chips; a heat dissipation plate on the spacer structure and including a plate bonding film in contact with an upper surface of the spacer structure and a plate body on the plate bonding film; heat dissipation posts extending between the package substrate and the heat dissipation plate in the vertical direction; and an encapsulant surrounding, with respect to a top-down view of the semiconductor package, at least a portion of the semiconductor chip stack, the wire bonds, the spacer structure, the heat dissipation plate, and the heat dissipation posts on the package substrate, wherein the plate body is formed of a material different from that of the plate bonding film.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic cross-sectional view illustrating a semiconductor package according to embodiments;

FIG. 2 is a schematic plan view illustrating a semiconductor package according to embodiments;

FIG. 3 is a schematic cross-sectional view illustrating a semiconductor package according to embodiments;

FIG. 4 is a schematic cross-sectional view illustrating a semiconductor package according to embodiments;

FIG. 5 is a schematic cross-sectional view illustrating a semiconductor package according to embodiments;

FIGS. 6 to 12 are cross-sectional views illustrating a sequential process of a method of manufacturing a semiconductor package according to embodiments; and

FIGS. 13 and 14 are cross-sectional views illustrating a sequential process of a method of manufacturing a semiconductor package according to embodiments.

### DETAILED DESCRIPTION

Hereinafter, embodiments of the present inventive concept will be described with reference to the accompanying drawings.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

Ordinal numbers such as “first,” “second,” “third,” etc. may be used simply as labels of certain elements, steps, etc., to distinguish such elements, steps, etc. from one another, Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

As used herein, components described as being “electrically connected” are configured such that an electrical signal can be transferred from one component to the other (although such electrical signal may be attenuated in strength as it is transferred and may be selectively transferred).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

It will be understood that when an element is referred to as being “connected” or “coupled” to or “on” another element, it can be directly connected or coupled to or on the other element or intervening elements may be present. In contrast, when an element is referred to as being “directly connected,” “directly attached,” “directly joined,” or “directly coupled” to another element, or as “contacting” or “in contact with” another element (or using any form of the word “contact”), there are no intervening elements present at the point of contact.

Various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may have a planar surface having dimensions greater than wiring (e.g., X-Y horizontal dimensions of a pad are both greater than the width of an internal writing to which it is connected) to promote an electrical connection to a further terminal, such as a bump or solder ball, and/or an external wiring.

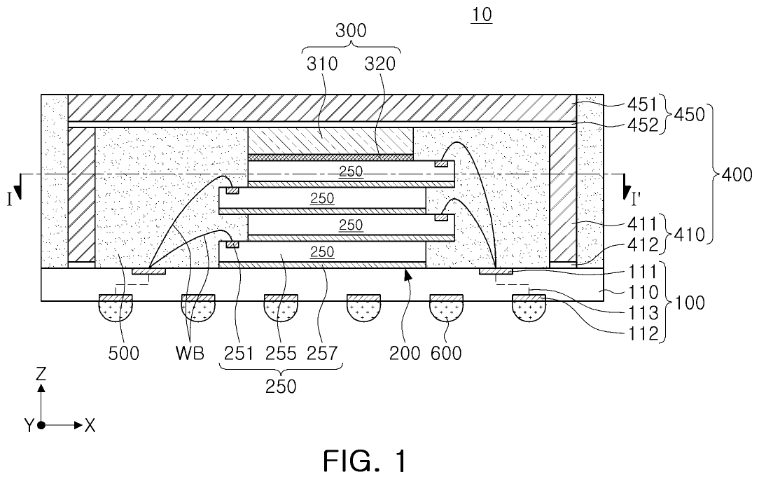

FIG. 1 is a schematic cross-sectional view illustrating a semiconductor package according to embodiments.

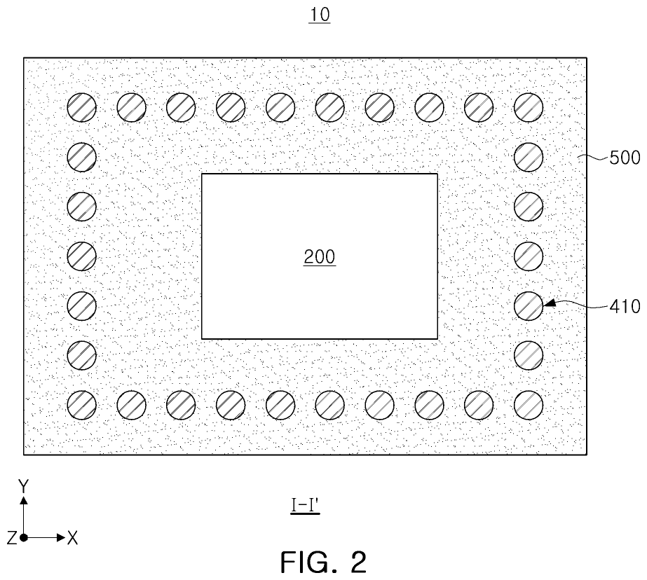

FIG. 2 is a schematic plan view illustrating a semiconductor package according to embodiments. FIG. 2 schematically illustrates a cross-section of a semiconductor package 10 of FIG. 1 taken along line I-I′.

Referring to FIGS. 1 and 2, the semiconductor package 10 may include a package substrate 100, a semiconductor chip stack 200, a spacer structure 300, a heat dissipation structure 400, an encapsulant 500, and connecting conductors 600.

The package substrate 100 may be a support substrate on which the semiconductor chip stack 200 is mounted and may be a semiconductor package substrate including a printed circuit board (PCB), a ceramic substrate, a glass substrate, a tape wiring board, etc. For example, the package substrate 100 may be a one-sided PCB, a double-sided PCB, or a multi-layer PCB. The package substrate 100 may include a substrate body 110, upper pads 111, lower pads 112, and an interconnection circuit 113.

The substrate body 110 may have an upper surface extending in an X-direction and a Y-direction and may have a lower surface opposite the upper surface. The semiconductor chip stack 200 may be mounted on the upper surface of the substrate body 110. The substrate body 110 may include an insulating material protecting the interconnection circuit 113, for example, a thermosetting resin, such as an epoxy resin, a thermoplastic resin, such as a polyimide, or a prepreg Ajinomoto build-up film (ABF), flame retardant 4 (FR4), etc. including an inorganic filler or/and glass fiber (glass cloth, glass fabric).

The upper pads 111 may be arranged on the upper surface of the substrate body 110. The upper pads 111 may be spaced apart from the semiconductor chip stack 200 on the upper surface of the substrate body 110. The upper pads 111 may be electrically connected to a plurality of semiconductor chips 250 of the semiconductor chip stack 200 via connecting wires WB. The connecting wires WB are conductive wires and may be wire bonds. Alternatively, as described below, the semiconductor package 10 can comprise one or more through substrate vias (TSVs) to form electrical connections between the package substrate 100 and the plurality of semiconductor chips 250, such that the semiconductor package 10 is not limited to the illustrated connecting wires WB. The upper pads 111 may be arranged side by side on one side surface of the semiconductor chip stack 200 and may include more or fewer than those illustrated in FIG. 1. The upper pads 111 may include, for example, at least one metal material among aluminum (Al), copper (Cu), nickel (Ni), tungsten (W), platinum (Pt), and gold (Au), but are not limited thereto.

The lower pads 112 may be arranged on the lower surface of the substrate body 110 opposite the upper surface. The lower pads 112 may be electrically connected to the upper pads 111 via the interconnection circuits 113. Connecting conductors 600 may be arranged below the lower pads 112, respectively. The lower pads 112 may include more or fewer than those illustrated in FIG. 1. The lower pads 112 may include, for example, at least one metal material selected from the group consisting of aluminum (Al), copper (Cu), nickel (Ni), tungsten (W), platinum (Pt), and gold (Au), but are not limited thereto.

The interconnection circuit 113 may electrically connect the upper pads 111 and the lower pads 112 within the substrate body 110. Although schematically illustrated in FIG. 1, the interconnection circuit 113 may include electrically conductive patterns and conductive vias forming an electrical connection path. The interconnection circuit 113 illustrated in FIG. 1 is a schematic illustration of the electrical connection path formed by the conductive patterns and conductive vias and is not intended to limit the lower pads 112 connected to the interconnection circuit 113. At least some of the lower pads 112 may be electrically connected to the upper pads 111 through the interconnection circuit 113 according to the present invention. Some of the lower pads 112 may be dummy pads that are not electrically connected to the upper pads 111. The interconnection circuit 113 may include at least one metal among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or an alloy including two or more metals.

The semiconductor chip stack 200 may be mounted on the package substrate 100 by wire bonding or flip-chip bonding. The semiconductor chip stack 200 may include a plurality of semiconductor chips 250 stacked in a vertical direction (e.g., in a Z-direction). Each of the plurality of semiconductor chips 250 may be arranged such that a chip bonding film 257 faces the package substrate 100. The plurality of semiconductor chips 250 may be stacked in a shifted form such that each of the chip pads 251 is exposed. For example, each of the chip pads 251 are at an external location of the chip body 255 toward side surfaces of the chip body 255, and the chip pads 251 are uncovered. Each of the plurality of semiconductor chips 250 may be electrically connected to upper pads 111 located at the upper surface of the package substrate 100 by the connecting wires WB. Each of the plurality of semiconductor chips 250 may be attached to one another by the chip bonding film 257. The semiconductor chip stack 200 may include more or fewer semiconductor chips 250 than illustrated. Each of the plurality of semiconductor chips 250 may be a memory chip including a memory circuit, such as a volatile memory, such as a dynamic RAM (DRAM), a static RAM (SRAM) and a nonvolatile memory, such as a phase change RAM (PRAM), a magnetic RAM (MRAM), a resistive RAM (RRAM), and a flash memory. In an embodiment, at least some of the plurality of semiconductor chips 250 may be a logic chip including a logic circuit, such as a central processing unit (CPU), a graphics processing unit (GPU), a field programmable gate array (FPGA), an application processor (AP), a digital signal processor, an encryption processor, a microprocessor, a microcontroller, an analog-to-digital converter, and an application-specific IC (ASIC). The plurality of semiconductor chips 250 may be the same or different types of semiconductor chips. Each of the plurality of semiconductor chips 250 may include a chip body 255, chip pads 251 disposed on an upper surface of the chip body 255, and the chip bonding film 257 disposed on a lower surface of the chip body 255.

The chip body 255 may have a front surface on which the chip pads 251 are arranged and a rear surface opposite to the front surface. The front surface of the chip body 255 may be referred to as an upper surface, and the rear surface of the chip body 255 may be referred to as a lower surface. A semiconductor device may be disposed inside the chip body 255.

The chip bonding film 257 may be disposed below the lower surface of the chip body 255, may constitute the lower surface of the semiconductor chip 250, and may fix the semiconductor chip 250 to another semiconductor chip 250 or to the substrate body 110. The chip bonding film 257 of the lowest semiconductor chip 250 located at the bottom among the plurality of semiconductor chips 250 may be in contact with the upper surface of the substrate body 110 and may attach the lowest semiconductor chip 250 to the substrate body 110. In an embodiment, the chip bonding film 257 may include an insulating material and may include a die attach film (DAF).

The spacer structure 300 may be disposed on the semiconductor chip stack 200. The spacer structure 300 may be disposed on the upper surface of the uppermost semiconductor chip 250 located on the highest level among the plurality of semiconductor chips 250 included in the semiconductor chip stack 200. The lower surface of the spacer structure 300 may be in contact with the upper surface of the uppermost semiconductor chip 250. The upper surface of the spacer structure 300 may be located on a level higher than upper ends of the connecting wires WB connected to the uppermost semiconductor chip 250. The upper surface of the spacer structure 300 may be located on substantially the same level as upper surfaces of heat dissipation posts 410. A footprint of the spacer structure 300, with respect to a top-down view of the semiconductor package 10, may be smaller than a footprint of each of the plurality of semiconductor chips 250. The footprint of the spacer structure 300 is the area occupied, or taken up by, the spacer structure 300 with respect to a top-down view of the semiconductor package 10 in the Z-direction. The footprint of a semiconductor chip 250 is the area occupied, or taken up by, the semiconductor chip with respect to a top-down view of the semiconductor package 10 in the Z-direction. The spacer structure 300 may be located in a laterally offset position, relative to the X-direction and/or Y-direction, from the uppermost semiconductor chip 250 so that the chip pads 251 of the uppermost semiconductor chip 250 are exposed. For example, with the spacer structure 300 laterally offset from the uppermost semiconductor chip 250, the spacer structure 300 may cover or overlap some of the uppermost semiconductor chip 250, but the spacer structure 300 does not cover or overlap the chip pad 251 of the uppermost semiconductor chip 250. Accordingly, with respect to FIG. 1, a dimension (e.g., width) of the spacer structure 300 in the X-direction may be less than a dimension (e.g., width) of the uppermost semiconductor chip 250. As illustrated, a side surface of the spacer structure 300 may be coplanar with a side surface of the uppermost semiconductor chip 250, while an opposing side surface of the spacer structure 300 may not be coplanar with an opposing side surface of the uppermost semiconductor chip 250. A space for the connecting wires WB connected to the uppermost semiconductor chip 250 is provided due to the spacer structure 300 not covering or overlapping the chip pad 251 of the uppermost semiconductor chip 250. Heat generated by the semiconductor chip stack 200 may be transferred to a heat dissipation plate 450 through the spacer structure 300. The spacer structure 300 may be a dummy configuration not electrically connected to the plurality of semiconductor chips 250 included in the semiconductor chip stack 200. By being a dummy configuration, the spacer structure 300 may not comprise an active or passive electrical device. In an embodiment, the spacer structure 300 may have the same or similar shape as that of the plurality of semiconductor chips 250 and may be a dummy chip including the same or similar material as that of the plurality of semiconductor chips 250. The spacer structure 300 may include a spacer bonding film 320 and a spacer body 310 on, and in contact with, the spacer bonding film 320.

The spacer bonding film 320 may constitute the lower surface of the spacer structure 300 and may fix the spacer structure 300 on the semiconductor chip stack 200. The spacer bonding film 320 may be a thermal interface material (TIM) layer transferring heat generated by the semiconductor chip stack 200 upward. In an embodiment, the spacer bonding film 320 may include an electrically insulating material and may include a die attach film (DAF).

The spacer body 310 may be disposed on the spacer bonding film 320 and the spacer body 310 may be in contact with the lower surface of the heat dissipation plate 450. The upper surface of the spacer body 310 may be positioned on substantially the same level as that of the upper surface of the heat dissipation posts 410. The spacer body 310 may be formed of an electrically and thermally conductive material, for example, a material having excellent thermal conductivity. The spacer body 310 may be formed of a material having a higher thermal conductivity than the encapsulant 500. For example, the spacer body 310 may include aluminum (Al), gold (Au), silver (Ag), copper (Cu), iron (Fe), graphite, graphene, etc. The spacer body 310 can comprise a thermal conductivity that is greater than

$$70 \frac{Watts}{meter \times Kelvin} ( \frac{W}{m \times K} )$$

at room temperature (25° Celsius), or greater than

$$75 \frac{W}{m \times K}$$

at room temperature (25° Celsius), or greater than

$$80 \frac{W}{m \times K}$$

at 25° Celsius, or greater than

$$85 \frac{W}{m \times K}$$

at 25° Celsius, or greater than

$$300 \frac{W}{m \times K}$$

at 25° Celsius, or greater than

$$400 \frac{W}{m \times K}$$

### at 25° Celsius.

The heat dissipation structure 400 may be disposed on the package substrate 100 and may include a plurality of heat dissipation posts 410 and the heat dissipation plate 450.

The plurality of heat dissipation posts 410 may be arranged on the package substrate 100, and the plurality of heat dissipation posts 410 may be spaced apart from the semiconductor chip stack 200 in a horizontal direction, for example, relative to the X-direction or the Y-direction. The plurality of heat dissipation posts 410 may be arranged to surround the semiconductor chip stack 200. The plurality of heat dissipation posts 410 may be spaced apart from each other. Referring to FIG. 2, although the plurality of heat dissipation posts 410 are illustrated as being arranged in one row, the arrangement of the plurality of heat dissipation posts 410 is not limited thereto. For example, the plurality of heat dissipation posts 410 may be arranged in two or three or more rows and surround the semiconductor chip stack 200. As used herein, in the context of the plurality of heat dissipation posts 410 surrounding the semiconductor chip stack 200, the term ‘surround’ can comprise two or more heat dissipation posts 410 on each side of the semiconductor chip stack 200. For example, with reference to FIG. 2, by surrounding the semiconductor chip stack 200, the plurality of heat dissipation posts 410 can comprise a first row of heat dissipation posts 410 that are arranged along the X-direction, and a second row of heat dissipation posts 410 that are arranged along the X-direction, with the first row spaced apart from the second row such that the semiconductor chip stack 200 is between the first row and the second row. The first row can comprise two or more heat dissipation posts 410, and the second row can comprise two or more heat dissipation posts 410. Further, by surrounding the semiconductor chip stack 200, the plurality of heat dissipation posts 410 can comprise a first column of heat dissipation posts 410 that are arranged along the Y-direction, and a second column of heat dissipation posts 410 that are arranged along the Y-direction, with the first column spaced apart from the second column such that the semiconductor chip stack 200 is between the first column and the second column. The first column can comprise two or more heat dissipation posts 410, and the second column can comprise two or more heat dissipation posts 410. FIG. 2 illustrates the heat dissipation posts 410 arranged in a shape (e.g., rectangular shape) that matches a shape of the semiconductor chip stack 200 (e.g., rectangular shape) as viewed in a top-down direction along the Z-direction. However, the heat dissipation posts 410 can be arranged in shapes that may or may not match the shape of the semiconductor chip stack 200, and may be arranged in other shapes such as other quadrilateral shapes (e.g., a square shape), rounded or circular shapes, irregular shapes, etc. In addition, FIG. 2 illustrates a separating distance between the semiconductor chip stack 200 and one of the first row or the second row of heat dissipation posts 410 as being different than, for example, less than, a separating distance between the semiconductor chip stack 200 and one of the first column or the second column of heat dissipation posts 410. However, these separating distances could be altered based on factors such as thermal conductivity, dimensions, etc., such that the separating distance between the semiconductor chip stack 200 and one or both of the columns could be equal to, or less than, the separating distance between the semiconductor chip stack 200 and one or both of the rows. The plurality of heat dissipation posts 410 may extend in the vertical direction (the Z-direction) and may penetrate the encapsulant 500. A cross-section of each of the plurality of heat dissipation posts 410 may have a circular shape, but is not limited thereto. For example, the cross-section of each of the plurality of heat dissipation posts 410 may have a polygonal shape, such as a square or a triangle, as well as an oval shape. The upper surfaces of the plurality of heat dissipation posts 410 may be in contact with the lower surface of the heat dissipation plate 450, and the lower surfaces of the plurality of heat dissipation posts 410 may be in contact with the upper surface of the package substrate 100. The plurality of heat dissipation posts 410 may receive heat generated in the horizontal direction (e.g., in the X-direction or the Y-direction) from the semiconductor chip stack 200 and dissipate the heat to the outside of the semiconductor package. The plurality of heat dissipation posts 410 may not be electrically connected to the upper pads 111, the interconnection circuit 113, and the lower pads 112 of the package substrate 100. Each of the plurality of heat dissipation posts 410 may include a post bonding film 412 and a post body 411.

The post bonding film 412 may be in contact with a lower surface of the heat dissipation post 410 and may be in contact with the upper surface of the substrate body 110. The post bonding film 412 may secure the heat dissipation post 410 on the substrate body 110. The plurality of heat dissipation posts 410 may be arranged on the package substrate 100 by a low-cost process, such as bonding, by including the post bonding film 412. In an embodiment, the post bonding film 412 may be formed of an electrically insulating material and may include a die attach film (DAF). In an embodiment, when the heat dissipation post 410 is formed by a method, such as plating or deposition, rather than a bonding method, the heat dissipation post 410 may not include the post bonding film 412.

The post body 411 may extend in the vertical direction (the Z-direction) on the post bonding film 412. The post body 411 may be formed of an electrically and thermally conductive material, for example, a material having excellent thermal conductivity. The post body 411 may be formed of a material having higher thermal conductivity than that of the encapsulant 500. For example, the post body 411 may include aluminum (Al), gold (Au), silver (Ag), copper (Cu), iron (Fe), graphite, graphene, etc. The post body 411 can comprise a thermal conductivity that is greater than

$$70 \frac{Watts}{meter \times Kelvin} ( \frac{W}{m \times K} )$$

at room temperature (25° Celsius), or greater than

$$75 \frac{W}{m \times K}$$

at room temperature (25° Celsius), or greater than

$$80 \frac{W}{m \times K}$$

at 25° Celsius, or greater than

$$85 \frac{W}{m \times K}$$

at 25° Celsius, or greater than

$$300 \frac{W}{m \times K}$$

at 25° Celsius, or greater than

$$400 \frac{W}{m \times K}$$

### at 25° Celsius.

The heat dissipation plate 450 may cover the upper surface of the spacer structure 300 and the upper surfaces of the plurality of heat dissipation posts 410. The heat dissipation plate 450 may cover the entire upper surface of the spacer structure 300 and the entire upper surface of each of the plurality of heat dissipation posts 410. Accordingly, the heat dissipation plate 450 can overlap the semiconductor chip stack 200 and the plurality of heat dissipation posts 410 in a vertical direction. The heat dissipation plate 450 can comprise a footprint that is greater than a footprint of the spacer structure 300, wherein the footprint is with respect to a top-down view of the semiconductor package 10. In addition, the heat dissipation plate 450 can comprise a footprint that is greater than a footprint of the semiconductor chip stack 200, wherein the footprint is with respect to a top-down view of the semiconductor package 10. An outer surface of the heat dissipation plate 450 may be positioned on the same line as that of a portion of a side surface of some of the plurality of heat dissipation posts 410. For example, by being positioned on the same line, an axis extending along, parallel to, and through the outer surface of the heat dissipation plate 450 can also extend along, parallel to, and through the side surface of some of the plurality of heat dissipation posts 410. If the outer surface of the heat dissipation plate 450 and the side surface of some of the plurality of heat dissipation posts 410 are planar, then being positioned on the same line can comprise the outer surface of the heat dissipation plate 450 being co-planar with the side surface of some of the plurality of heat dissipation posts 410. FIG. 1 illustrates the heat dissipation plate 450 being positioned on the same line as some of the plurality of heat dissipation posts 410. Accordingly, as illustrated in FIG. 1, a width of the heat dissipation plate 450 between opposing outer surfaces of the heat dissipation plate 450 along an axis in the X-direction may be equal to a separating distance between side surfaces of opposing heat dissipation posts 410 along the axis in the X-direction. The heat dissipation plate 450 may dissipate heat generated by the semiconductor chip stack 200 in the vertical direction (the Z-direction) to the outside of the semiconductor package. The heat dissipation plate 450 may include a plate bonding film 452 and a plate body 451.

The plate bonding film 452 may constitute a lower surface of the heat dissipation plate 450 and may fix the heat dissipation plate 450 on the spacer structure 300. The plate bonding film 452 may have a lower surface having a curve according to the upper surface of the spacer structure 300 and the upper surface of each of the plurality of heat dissipation posts 410. Accordingly, even if there is a difference in the level on which the upper surface of the spacer structure 300 and the upper surface of each of the plurality of heat dissipation posts 410 are located, the heat dissipation plate 450 may be stably fixed. In an embodiment, the plate bonding film 452 may include an insulating material and may include a die attach film (DAF).

The plate body 451 may be disposed on the plate bonding film 452. The plate body 451 may be formed of an electrically and thermally conductive material, for example, a material having excellent thermal conductivity. The plate body 451 may be formed of a material having higher thermal conductivity than that of the encapsulant 500. For example, the plate body 451 may include aluminum (Al), gold (Au), silver (Ag), copper (Cu), iron (Fe), graphite, graphene, etc. The plate body 451 can comprise a thermal conductivity that is greater than

$$70 \frac{Watts}{meter \times Kelvin} ( \frac{W}{m \times K} )$$

at room temperature (25° Celsius), or greater than

$$75 \frac{W}{m \times K}$$

at room temperature (25° Celsius), or greater than

$$80 \frac{W}{m \times K}$$

at 25° Celsius, or greater than

$$85 \frac{W}{m \times K}$$

at 25° Celsius, or greater than

$$300 \frac{W}{m \times K}$$

at 25° Celsius, or greater than

$$400 \frac{W}{m \times K}$$

### at 25° Celsius.

By including the heat dissipation structure 400 including the plurality of heat dissipation posts 410 and the heat dissipation plate 450, the semiconductor package according to the present invention may dissipate heat generated by the semiconductor chip stack 200 in the horizontal and vertical directions and may improve the heat dissipation characteristics of the semiconductor package. The spacer structure 300 may further improve the heat dissipation characteristics toward the top by contacting both the uppermost semiconductor chip 250 and the heat dissipation plate 450. Further, the dimension of the spacer structure 300 and position of the spacer structure 300 relative to the uppermost semiconductor chip 250 provide a space for the connecting wires WB to connect to a chip pad 251 of the uppermost semiconductor chip 250. Accordingly, the semiconductor package provides improved reliability. Since at least some of the components included in the semiconductor package according to the present inventive concept are fixed and arranged by a bonding film included in each component, the process cost and process difficulty may be lower than a process of forming each component by a method, such as deposition or plating. For example, since the heat dissipation plate 450 is fixed and disposed by the plate bonding film 452, the heat dissipation plate 450 may be disposed by a bonding process, and the process cost and process difficulty may be lower than those of the method of forming the heat dissipation plate 450 through deposition.

The encapsulant 500 may surround, with respect to a top-down view of the semiconductor package 10, the semiconductor chip stack 200, the spacer structure 300, and the heat dissipation structure 400 on the package substrate 100. The encapsulant 500 may encapsulate at least a portion of the semiconductor chip stack 200. The encapsulant 500 may surround the side surface of the heat dissipation plate 450, and the upper surface of the heat dissipation plate 450 may be exposed and uncovered. An uppermost surface of the encapsulant 500 may be coplanar with the upper surface of the heat dissipation plate 450. The outer surface of the encapsulant 500 may be coplanar with the outer surface of the package substrate 100. The encapsulant 500 may include, for example, a thermosetting resin, such as an epoxy resin, a thermoplastic resin, such as polyimide, or a prepreg, ABF, FR-4, BT, epoxy molding compound (EMC) obtained by impregnating an inorganic filler, etc. with these resins. For example, the encapsulant 500 may include EMC.

The connecting conductors 600 may be arranged below the package substrate 100. The connecting conductors 600 may be arranged below the lower pads 112 of the package substrate 100. The connecting conductors 600 may be electrically connected to the interconnection circuit 213 through the lower pads 112 and may be electrically connected to the semiconductor chip stack 200 through the upper pads 111 and the connecting wires WB. The semiconductor package 10 may be connected to an external device through the connecting conductors 600. The connecting conductors 600 may have a spherical or oval shape formed of, for example, a low-melting point metal, such as tin (Sn), indium (In), bismuth (Bi), antimony (Sb), copper (Cu), silver (Ag), zinc (Zn), lead (Pb), or alloys thereof (for example, Sn-Ag-Cu).

In the description of the embodiments below, the same description as that given above with reference to FIGS. 1 and 2 will be omitted.

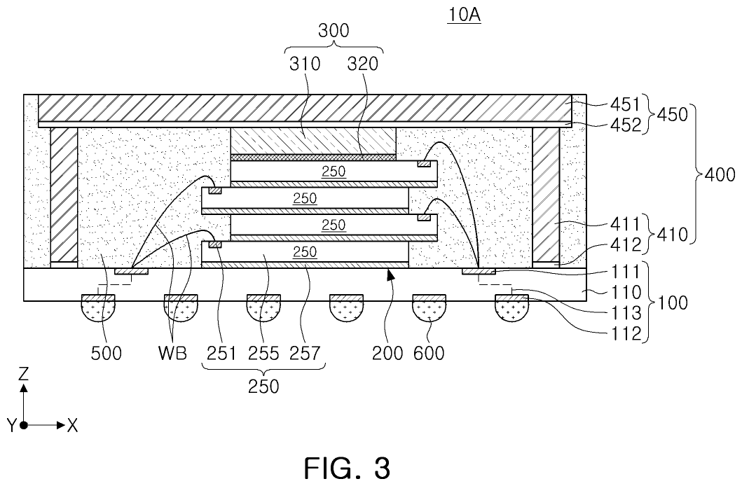

FIGS. 3 to 5 are schematic cross-sectional views illustrating semiconductor packages according to embodiments. FIGS. 3 to 5 illustrate regions corresponding to the cross-sectional views of FIG. 1.

Referring to FIG. 3, unlike the semiconductor package 10 of FIG. 1, a semiconductor package 10A may have a plurality of heat dissipation posts 410 arranged inwardly relative to the outer surface of the heat dissipation plate 450. Since the plurality of heat dissipation posts 410 and the heat dissipation plate 450 may be formed through separate processes, they may be arranged in a shifted manner relative to the plurality of heat dissipation posts 410 arranged around the semiconductor chip stack 200. While FIG. 1 illustrates the outer surface of the heat dissipation plate 450 in line with the side surface of some of the plurality of heat dissipation posts 410, FIG. 3 illustrates the outer surface of the heat dissipation plate 450 as being not in line with the side surface of the plurality of heat dissipation posts 410. Accordingly, as illustrated in FIG. 3, a width of the heat dissipation plate 450 between opposing outer surfaces of the heat dissipation plate 450 along an axis in the X-direction may be greater than a separating distance between side surfaces of opposing heat dissipation posts 410 along the axis in the X-direction. Since the semiconductor package 10A is formed to have a large flat surface so that all of the plurality of heat dissipation posts 410 may be arranged inwardly relative to the outer surface of the heat dissipation plate 450, the difficulty of the arrangement process of the heat dissipation plate 450 may be reduced.

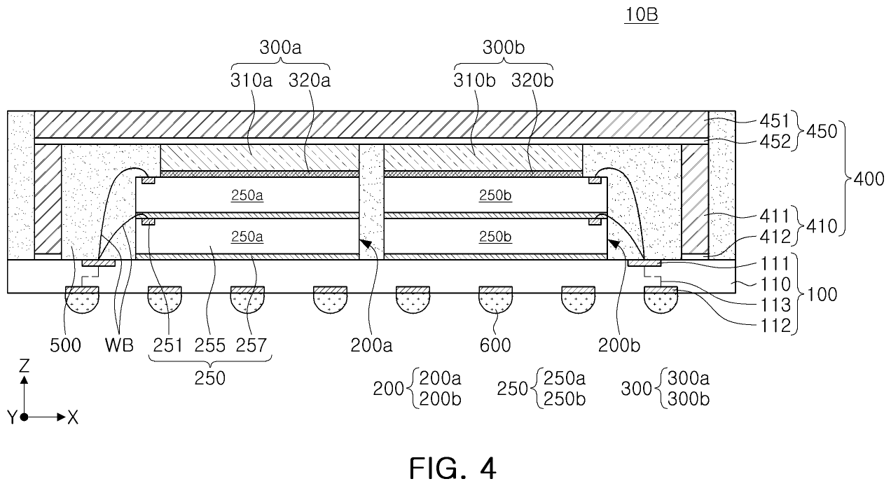

Referring to FIG. 4, unlike the semiconductor package 10 of FIG. 1, the semiconductor chip stack 200 of a semiconductor package 10B may include a plurality of stacks. For example, the semiconductor chip stack 200 may include a first stack 200a and a second stack 200b, and the first stack 200a and the second stack 200b may be spaced apart from each other in the horizontal direction, for example, the X-direction. The first stack 200a may include first semiconductor chips 250a, and the second stack 200b may include second semiconductor chips 250b. The spacer structure 300 may be arranged on each semiconductor chip stack 200. For example, a first spacer structure 300a may be disposed on the first stack 200a, and a second spacer structure 300b may be disposed on the second stack 200b. The first spacer structure 300a and the second spacer structure 300b may be in contact with the heat dissipation plate 450. When the semiconductor package 10B includes a plurality of semiconductor chip stacks 200, the spacer structure 300 may be disposed on each of the semiconductor chip stacks 200, and heat dissipation characteristics may be improved similarly to the semiconductor package 10 of FIG. 1. Alternatively, if the semiconductor package 10B does not comprise the spacer structure 300, then the first stack 200a may be in contact with the heat dissipation plate 450 without intervening structures between a top of the first stack 200a and the plate bonding film 452. Likewise, if the semiconductor package 10B does not comprise the spacer structure 300, then the second stack 200b may be in contact with the heat dissipation plate 450 without intervening structures between a top of the second stack 200b and the plate bonding film 452.

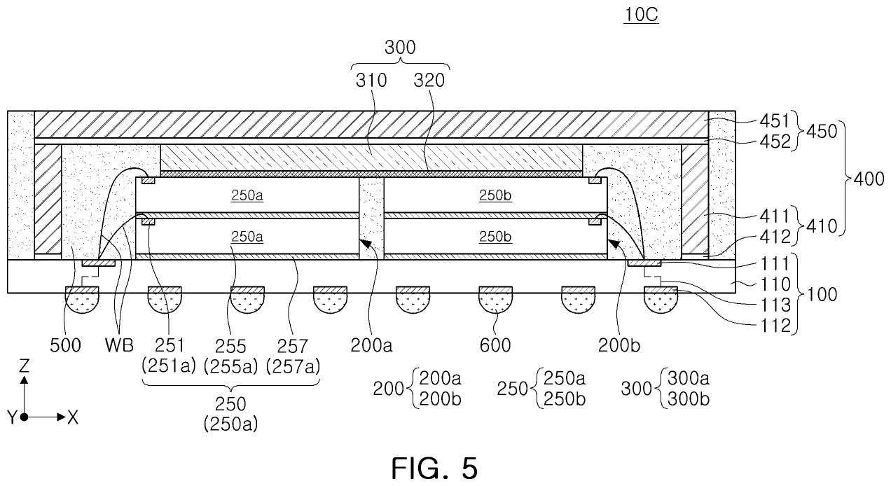

Referring to FIG. 5, unlike the semiconductor package 10B of FIG. 4, a single spacer structure 300 may be disposed on the plurality of semiconductor chip stacks 200 of a semiconductor package 10C. In the vertical direction (the Z-direction), the chip pads 251 of each of the plurality of semiconductor chips 250 may not be covered by, or overlapped by, the spacer structure 300. A footprint of the spacer structure 300 may be larger than a footprint of each of the first semiconductor chips 250a and the second semiconductor chips 250b. For example, the footprint of the spacer structure 300 may be larger than the footprint of the first semiconductor chip 250a, and the footprint of the spacer structure 300 may be larger than the footprint of the second semiconductor chip 250b. The number and arrangement of the spacer structure 300, the plurality of heat dissipation posts 410, etc. are not limited to the embodiments described above.

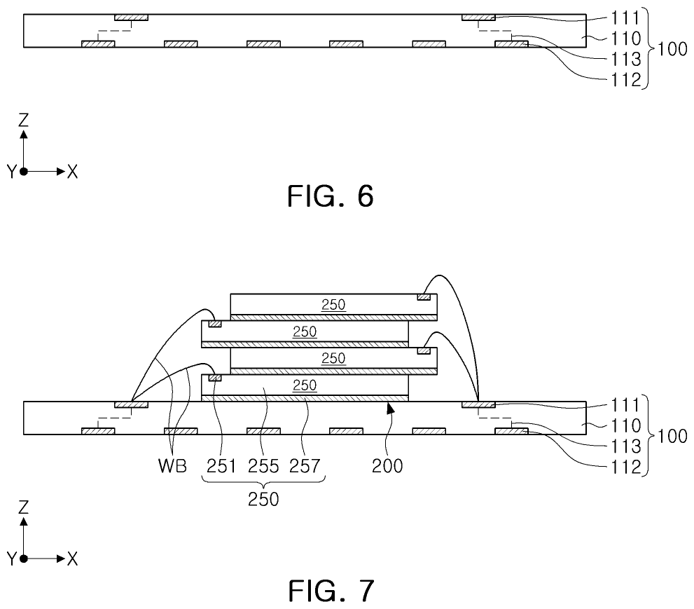

FIGS. 6 to 12 are cross-sectional views illustrating a sequential process of a method of manufacturing a semiconductor package according to embodiments. FIGS. 6 to 12 illustrate a region corresponding to the cross-sectional view of FIG. 1.

Referring to FIG. 6, the package substrate 100 including the substrate body 110 on which the upper pads 111, the lower pads 112, and the interconnection circuits 113 are arranged may be prepared.

In an embodiment, depending on the type of the package substrate 100, conductive patterns and insulating layers may be repeatedly stacked within the package substrate 100, and conductive vias penetrating the insulating layers and connecting conductive patterns on different levels may be formed.

Referring to FIG. 7, a plurality of semiconductor chips 250 may be stacked on the package substrate 100 to form the semiconductor chip stack 200, and connecting wires WB may be formed.

The plurality of semiconductor chips 250 may be stacked and shifted with each other so that the chip pads 251 located on the upper surfaces thereof are exposed. The connecting wires WB may be formed to connect the exposed chip pads 251 and the upper pads 111 of the package substrate 100. The connecting wires WB can comprise wire bonds extending from the chip pads 251 to the upper pads 111 of the package substrate 100.

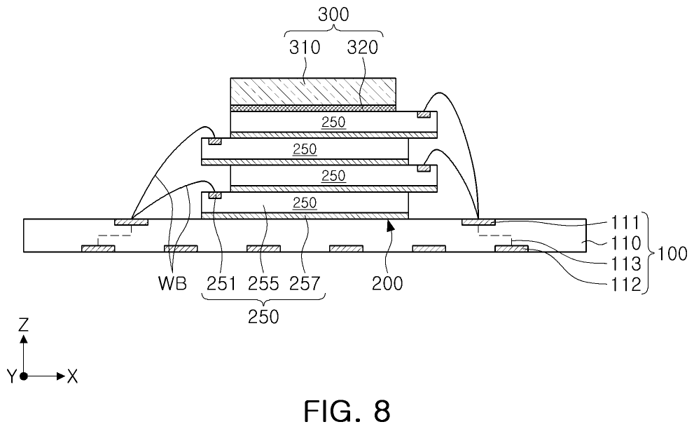

Referring to FIG. 8, the spacer structure 300 may be disposed on the semiconductor chip stack 200.

The spacer structure 300 may be fixed on the semiconductor chip stack 200 by the spacer bonding film 320 forming the lower surface of the spacer structure 300. The spacer structure 300 may be disposed so that the chip pads 251 of the uppermost semiconductor chip 250 located on the highest level among the plurality of semiconductor chips 250 are exposed and are not covered by the spacer structure 300.

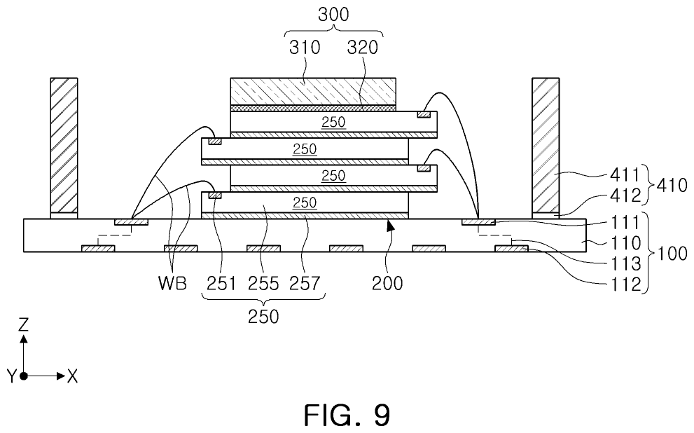

Referring to FIG. 9, the plurality of heat dissipation posts 410 may be arranged around the semiconductor chip stack 200.

The plurality of heat dissipation posts 410 may be spaced apart from the semiconductor chip stack 200 in the horizontal direction. Each of the plurality of heat dissipation posts 410 may be fixed on the package substrate 100 by the post bonding film 412, with the post bonding film 412 forming the lower surface of the heat dissipation posts 410. The upper surface of each of the plurality of heat dissipation posts 410 may be positioned on substantially the same level as that of the upper surface of the spacer structure 300. Since each of the plurality of heat dissipation posts 410 includes the post bonding film 412, the plurality of heat dissipation posts 410 may be arranged by a bonding process. The bonding process may have lower process cost and process difficulty than a process of forming the plurality of heat dissipation posts 410 by a method, such as plating or deposition. When forming the plurality of heat dissipation posts 410 by a method, such as plating or deposition, each of the plurality of heat dissipation posts 410 may not include the post bonding film 412.

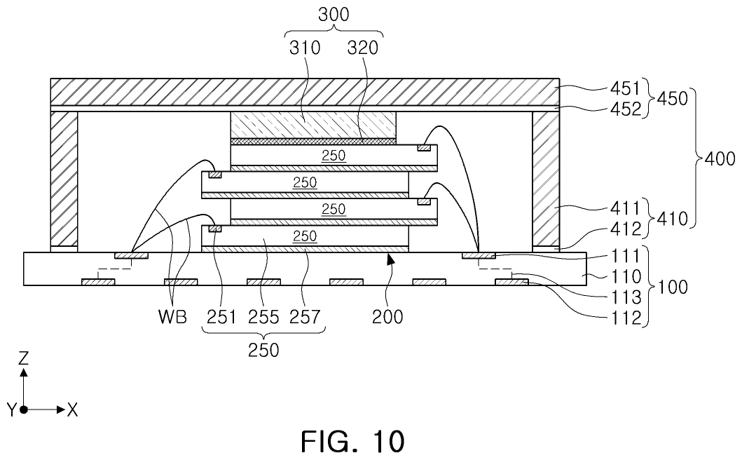

Referring to FIG. 10, the heat dissipation plate 450 may be disposed on the semiconductor chip stack 200 and the plurality of heat dissipation posts 410 to form the heat dissipation structure 400.

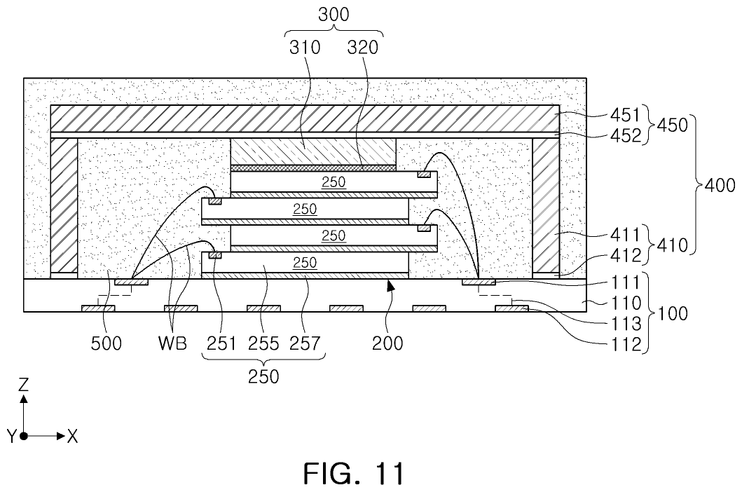

The heat dissipation plate 450 may be fixed to the upper surface of the spacer structure 300 and the upper surfaces of the plurality of heat dissipation posts 410 by the plate bonding film 452, with the plate bonding film 452 forming the lower surface of the heat dissipation plate 450. The heat dissipation plate 450 may be attached to the semiconductor stack 200 by the plate bonding film 452 using a bonding process that is the same as the bonding process used to stack and attach the chips of the semiconductor chip stack 200, and the process cost and process difficulty may be reduced compared to a process of forming the heat dissipation plate 450 by a method, such as deposition. For example, the bonding film 452 may identical to the chip bonding film 257 (and thus have the same thickness and material composition) and be attached to the bottom surface of the heat dissipation plate 450 in the same manner as the chip bonding film 257 is attached to the surfaces of the chips of the semiconductor chip stack 200. Similarly, the spacer structure may be attached to the semiconductor stack 200 using this same bonding process, and the spacer bonding film 320 may be identical to the chip bonding film 257 (and thus have the same thickness and material composition) and be attached to the bottom surface of the space body 310 in the same manner as the chip bonding film 257 is attached to the surfaces of the chips of the semiconductor chip stack 200. Referring to FIG. 11, the encapsulant 500 may be formed such that the encapsulant 500 can encapsulate at least a portion of the semiconductor chip stack 200.

The encapsulant 500 may be formed to cover and surround at least a portion of each of the semiconductor chip stack 200, the spacer structure 300, and the heat dissipation structure 400 on the package substrate 100. The encapsulant 500 may be formed, for example, by applying and curing EMC. As the plurality of heat dissipation posts 410 are arranged in a columnar shape and spaced apart from each other at a certain interval, the encapsulant 500 may be formed to encapsulate the plurality of semiconductor chips 250 located inside the plurality of heat dissipation posts 410. The encapsulant 500 can be formed in a single step, and the encapsulant 500 can comprise a single continuous homogenous layer. The encapsulant 500 may be formed on a level higher than that of the upper surface of the heat dissipation plate 450 to cover the upper surface of the heat dissipation plate 450.

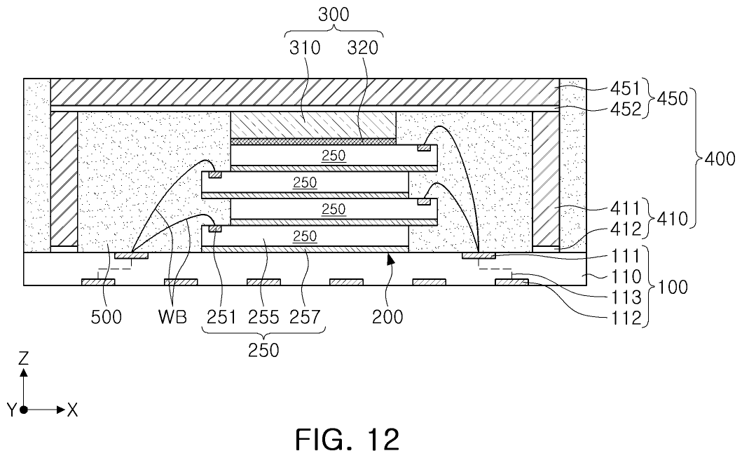

Referring to FIG. 12, a portion of the encapsulant 500 on a level higher than that of the upper surface of the heat dissipation plate 450 may be removed from the upper surface.

The encapsulant 500 may be partially removed from the upper surface by a method, such as grinding, and the upper surface of the heat dissipation plate 450 may be exposed, such that the upper surface of the heat dissipation plate 450 is no longer covered by the encapsulant 500. The encapsulant 500 can be in contact with side and lower surfaces of the heat dissipation plate 450 but the encapsulant 500 may not be in contact with the upper surface of the heat dissipation plate 450. An uppermost surface of the encapsulant 500 can be coplanar with an upper surface of the heat dissipation plate 450. Thereafter, referring to FIG. 1 together, the connecting conductors 600 may be formed below the lower pads 112 of the package substrate 100, thereby manufacturing the semiconductor package 10 of FIG. 1.

In the following description of the method of manufacturing the semiconductor package, redundant descriptions are omitted.

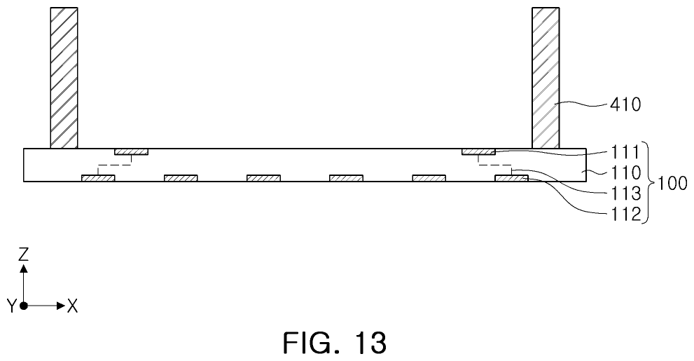

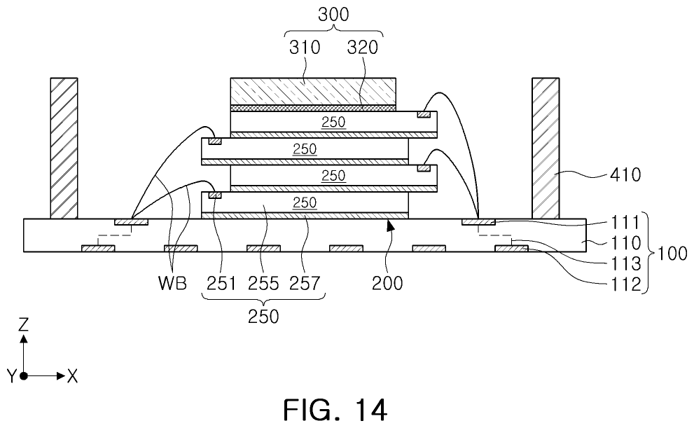

FIGS. 13 and 14 are cross-sectional views illustrating a sequential process of a method of manufacturing a semiconductor package according to embodiments. FIGS. 13 and 14 illustrate a region corresponding to the cross-sectional view of FIG. 1.

Referring to FIG. 13, unlike the manufacturing method of FIGS. 6 to 12, the plurality of heat dissipation posts 410 may be first formed on the package substrate 100.

The plurality of heat dissipation posts 410 may be formed by a plating or deposition method, and unlike the semiconductor package 10 of FIG. 1, the plurality of heat dissipation posts 410 may not include the post bonding film 412. In an embodiment, each of the plurality of heat dissipation posts 410 may include a metal seed layer forming a lower surface.

Referring to FIG. 14, the semiconductor chip stack 200 and the spacer structure 300 may be stacked.

Unlike the manufacturing method of FIGS. 6 to 12 in which the upper surfaces of the plurality of heat dissipation posts 410 are positioned on the same level as that of the upper surface of the spacer structure 300 in accordance with the already formed spacer structure 300, in the present manufacturing method, since the plurality of heat dissipation posts 410 are formed first, the semiconductor chip stack 200 may be stacked, and then the upper surface of the spacer structure 300 may be positioned on the same level as that of the upper surfaces of the plurality of heat dissipation posts 410. Since the spacer structure 300 can comprise a dummy configuration that is not electrically connected to the plurality of semiconductor chips 250, the height the spacer structure 300 may be freely adjusted. The subsequent process may be the same as or similar to FIGS. 6 to 12.

Though FIGS. 1-14 illustrate embodiments in which the semiconductor package 10 includes the spacer structure 300 (e.g., comprising the spacer body 310 and the spacer bonding film 320) on the upper surface of the uppermost semiconductor chip 250, the semiconductor package 10 is not so limited. Rather, the semiconductor package 10 can be arranged as a flip chip in which the semiconductor chip stack 200 is flipped, and/or the semiconductor package 10 can comprise one or more through substrate vias (TSV) to form an electrical connection between the semiconductor chip stack 200 and the package substrate 100. In these embodiments, the semiconductor package 10 may not comprise the spacer structure 300. Instead, an upper surface of the uppermost semiconductor chip 250 can be in contact with the heat dissipation plate 450 without an intervening layer (for example, the spacer structure 300) between the heat dissipation plate 450 and the upper surface of the uppermost semiconductor chip 250. The plate bonding film 452 may be in contact with the upper surface of the uppermost semiconductor chip 250 such that the plate bonding film 452 can fix the heat dissipation plate 450 to the upper surface of the uppermost semiconductor chip 250. Due to the heat dissipation plate 450 being formed of a material with excellent thermal conductivity, the heat dissipation plate 450 can function to dissipate heat from the semiconductor chip stack 200 while being in contact with the upper surface of the uppermost semiconductor chip 250.

In addition, while FIGS. 1-14 illustrate embodiments in which the semiconductor package 10 includes the connecting wires WB for electrically connecting the upper pads 111 to the plurality of semiconductor chips 250, the semiconductor package 10 is not so limited. Rather, the semiconductor package 10 can comprise one or more through substrate vias (TSVs) to electrically connect the semiconductor chip stack 200 and the package substrate 100. For example, a via, or hole, is formed in the semiconductor chip stack 200 and filled with an electrically conductive material to form an electrical connection. Accordingly, the semiconductor package 10 can comprise TSVs to facilitate an electrical connection instead of the connecting wires WB.

According to the embodiments of the present inventive concept, by including the heat dissipation structure having a dolmen structure, the semiconductor package having improved heat dissipation characteristics and improved reliability may be provided.

While embodiments have been shown and described above, it will be apparent to those skilled in the art that modifications and variations could be made without departing from the scope of the present inventive concept as defined by the appended claims.

What is claimed is:

1. A semiconductor package comprising:
a package substrate;
a semiconductor chip stack including a plurality of semiconductor chips arranged on, and electrically connected to, the package substrate;
a plurality of heat dissipation posts spaced apart from the semiconductor chip stack on the package substrate;
a heat dissipation plate on upper surfaces of the plurality of heat dissipation posts; and
an encapsulant surrounding, with respect to a top-down view of the semiconductor package, each of the semiconductor chip stack, the plurality of heat dissipation posts, and the heat dissipation plate on the package substrate.

2. The semiconductor package of claim 1, wherein the encapsulant surrounds side and lower surfaces of the heat dissipation plate, and an uppermost surface of the encapsulant is coplanar with an upper surface of the heat dissipation plate.

3. The semiconductor package of claim 1, further comprising a spacer structure on the semiconductor chip stack, wherein a lower surface of the heat dissipation plate is in contact with an upper surface of the spacer structure and the upper surface of each of the plurality of heat dissipation posts.

4. The semiconductor package of claim 1, wherein the plurality of heat dissipation posts and the heat dissipation plate are formed of a material having a higher thermal conductivity than that of the encapsulant.

5. The semiconductor package of claim 1, further comprising a spacer structure on the semiconductor chip stack, wherein the spacer structure includes a spacer bonding film in contact with the semiconductor chip stack and a spacer body on, and in contact with, the spacer bonding film.

6. The semiconductor package of claim 5, wherein the spacer body is formed of a material having a higher thermal conductivity than that of the encapsulant.

7. The semiconductor package of claim 1, wherein the heat dissipation plate overlaps the semiconductor chip stack and the plurality of heat dissipation posts in a vertical direction.

8. The semiconductor package of claim 1, wherein each of the plurality of heat dissipation posts includes a post bonding film in contact with an upper surface of the package substrate and a post body on, and in contact with, the post bonding film.

9. The semiconductor package of claim 8, wherein the post body of each of the plurality of heat dissipation posts is formed of a material having a higher thermal conductivity than that of the encapsulant.

10. The semiconductor package of claim 8, wherein the post bonding film is formed of an electrically insulating material, and the post body is formed of an electrically and thermally conductive material.

11. A semiconductor package comprising:
a package substrate;
a heat dissipation structure on the package substrate, wherein the heat dissipation structure includes a heat dissipation plate spaced apart from the package substrate in a vertical direction and a plurality of heat dissipation posts extending in the vertical direction between the heat dissipation plate and the package substrate;
a plurality of semiconductor chips below the heat dissipation plate on the package substrate, wherein the plurality of semiconductor chips include an uppermost semiconductor chip disposed on a highest level; and
a spacer structure between the heat dissipation plate and the plurality of semiconductor chips,
wherein a footprint of the spacer structure, with respect to a top-down view of the semiconductor package, is smaller than a footprint of each of the plurality of semiconductor chips.

12. The semiconductor package of claim 11, wherein the spacer structure includes a spacer bonding film in contact with the uppermost semiconductor chip and a spacer body on, and in contact with, the spacer bonding film.

13. The semiconductor package of claim 11, wherein the plurality of heat dissipation posts surround the plurality of semiconductor chips.

14. The semiconductor package of claim 11, wherein the plurality of heat dissipation posts and the heat dissipation plate include copper (Cu).

15. The semiconductor package of claim 11, wherein each of the plurality of semiconductor chips includes a chip bonding film formed on a lower surface thereof.

16. A semiconductor package comprising:
a semiconductor chip stack including a plurality of semiconductor chips stacked in a vertical direction, the plurality of semiconductor chips including chip pads located at upper surfaces thereof, respectively;
a package substrate below the semiconductor chip stack and including upper pads located at an upper surface thereof;
wire bonds extending from the chip pads of the plurality of respective semiconductor chips to the upper pads of the package substrate;
a spacer structure on the plurality of semiconductor chips;
a heat dissipation plate on the spacer structure and including a plate bonding film in contact with an upper surface of the spacer structure and a plate body on the plate bonding film;
heat dissipation posts extending between the package substrate and the heat dissipation plate in the vertical direction; and
an encapsulant surrounding, with respect to a top-down view of the semiconductor package, at least a portion of the semiconductor chip stack, the wire bonds, the spacer structure, the heat dissipation plate, and the heat dissipation posts on the package substrate,
wherein the plate body is formed of a material different from that of the plate bonding film.

17. The semiconductor package of claim 16, wherein the plate body is formed of an electrically and thermally conductive material, and the plate bonding film is formed of an electrically insulating material.

18. The semiconductor package of claim 16, wherein the plate body is formed of a material having a higher thermal conductivity than that of the encapsulant.

19. The semiconductor package of claim 18, wherein the heat dissipation posts are formed of the same material as the plate body.

20. The semiconductor package of claim 16, wherein the plate bonding film is in contact with the upper surface of each of the spacer structure and the heat dissipation posts.
